(19) United States
(12) Patent Application Publication
(10) Pub. No.: US 2024/0342749 A1
(43) Pub. Date: Oct. 17, 2024

(54) MASK AND MANUFACTURING METHOD THEREOF

(71) Applicant: DARWIN PRECISIONS CORPORATION, Hsinchu County (TW)

(72) Inventors: Ming-Hung Tsai, Hsinchu County (TW); Chi-Wei Lin, Hsinchu County (TW)

(21) Appl. No.: 18/383,486

(22) Filed: Oct. 25, 2023

(30) Foreign Application Priority Data
Apr. 12, 2023 (TW) 112113665

(51) Int. Cl. B05C 21/00; G03F 1/38; G03F 1/80

(52) U.S. Cl. CPC B05C 21/005; G03F 1/38; G03F 1/80

(57) ABSTRACT

A mask includes a first surface and a second surface opposite to the first surface, and has a total etching area and clearance areas. The mask has vias in the total etching area, and each via communicates the first surface with the second surface. The clearance areas are arranged in the total etching area, and the vias surround each clearance area. Each clearance area further has a through hole therein communicating the first surface with the second surface. Each clearance area is in a shape of a circle or a polygon. When each interior angle of the polygon is less than 120 degrees, the clearance area further comprises a first clearance region and a second clearance region surrounded by the first clearance region, and the mask has a plurality of etched grooves in the first clearance region. The disclosure further provides a manufacturing method of a mask.

### FIELD OF THE INVENTION

The disclosure relates to the technical field of evaporation, and more particularly to a mask.

### BACKGROUND OF THE INVENTION

With the evolution of light sources and backlight modules, the screen thickness of displays such as the liquid crystal display (LCD) has been significantly reduced. Due to the demand for thinner and lighter cell phones, organic light-emitting diode (OLED) displays have also evolved. Since there is no backlight module in the OLED display, the cell phone using the OLED display can be made thinner and lighter, and has the advantages of better picture quality and more power saving.

A fine metal mask is commonly used in the display industry. For example, in the manufacture of OLED display panels, the fine metal mask is used for evaporating a pixel material onto a substrate to form an array of pixels. During the evaporation process, it is required to align the mask with the substrate, and any factors affecting the mask structure can cause misalignment and evaporation errors. For example, even if the fine metal mask has a mark for alignment, when the mask is bent or uneven, it may interfere with the alignment of the mark, making the fine metal mask not available for use.

### SUMMARY OF THE INVENTION

The disclosure provides a mask which can avoid stress concentration and creasing caused by stress, further improve the accuracy of alignment operation and effectively monitor the thickness of the evaporation material layer when an evaporation is carried out.

A mask provided by the disclosure comprises a first surface and a second surface opposite to the first surface, and has a total etching area and a plurality of clearance areas. The mask has a plurality of vias in the total etching area, and each of the vias communicates the first surface with the second surface. The plurality of clearance areas are arranged in the total etching area, and the plurality of vias of the total etching area surround each of the clearance areas. Each clearance area further has a through hole therein, which communicates the first surface with the second surface. Each of the clearance areas is in a shape of a circle or a polygon. When each interior angle of the polygon is less than 120 degrees, the clearance area further comprises a first clearance region and a second clearance region. The first clearance region surrounds the second clearance region, and the mask has a plurality of etched grooves in the first clearance region.

In an example of the disclosure, a percentage of an area of the first clearance region relative to an area of the clearance area is greater than 5%, and the plurality of etched grooves are opened on the first surface or the second surface.

In an example of the disclosure, a percentage of an area of the first clearance region relative to an area of the clearance area is further greater than or equal to 10%.

In an example of the disclosure, the clearance area is in a shape of a rectangle, and the clearance area comprises the first clearance region and the second clearance region.

In an example of the disclosure, the total etching area further comprises a plurality of working areas, and the plurality of working areas are spaced apart from each other. The plurality of clearance areas are arranged on a periphery of each working area.

In an example of the disclosure, the total etching area further comprises a peripheral area surrounding the plurality of working areas. The plurality of clearance areas are further arranged between an edge of each working area and an edge of the mask.

The disclosure further provides a mask, which comprises a first surface and a second surface opposite to the first surface, and has a total etching area and a plurality of clearance areas. The mask has a plurality of vias in the total etching area, and each of the vias communicates the first surface with the second surface. The plurality of clearance areas are arranged in the total etching area. At least one of the clearance areas comprises a first clearance region and a second clearance region. The first clearance region surrounds the second clearance region. A percentage of an area of the first clearance region relative to an area of the at least one clearance area is greater than 5%. The mask has a plurality of etched grooves in the first clearance region, and the second clearance region has a through hole. The plurality of etched grooves are opened on the first surface or the second surface, and the through hole communicates the first surface with the second surface.

The disclosure further provides a manufacturing method of a mask, comprising: providing a plate, which has a first surface and a second surface opposite to each other, a total etching preparation area, and a plurality of clearance preparation areas; forming a first photoresist layer on the first surface of the plate, and forming a second photoresist layer on the second surface, the first photoresist layer having a plurality of first openings located in the total etching preparation area, and the second photoresist layer having a plurality of second openings located in the total etching preparation area; forming a plurality of first etching portions on the first surface and respectively corresponding to the plurality of first openings; forming a plurality of second etching portions on the second surface and respectively corresponding to the plurality of second openings; and communicating each first etching portion with each second etching portion, and forming a plurality of vias.

In the disclosure, the clearance area is in the shape of a circle or polygon, and each interior angle of the polygon is greater than or equal to 120 degrees, so it is less likely to form regional stress concentration, thus avoiding creasing. In the disclosure, the clearance area can comprise the first clearance region and the second clearance region, and the first clearance region has the plurality of etched grooves and surrounds the second clearance region, which thereby can reduce the structural difference between the clearance area and the total etching area and reduce the stress gradient, thereby avoiding creasing. The disclosure further helps in improving the accuracy of alignment operation and monitoring the thickness of the evaporation material layer effectively when an evaporation is carried out. The manufacturing method of the disclosure helps in improving the yield rate and usability of the mask.

Other objectives, features and advantages of the invention will be further understood from the further technological features disclosed by the embodiments of the invention wherein there are shown and described preferred embodiments of this invention, simply by way of illustration of modes best suited to carry out the invention.

### BRIEF DESCRIPTION OF THE DRAWINGS

FIG. 1 is a schematic top view of a mask according to a first example of the disclosure.

FIG. 2 is a partial enlarged view of FIG. 1.

FIG. 3 is a schematic partial sectional view of FIG. 2 taken along line A-A′.

FIG. 4A and FIG. 4B are schematic views showing photos of the example of FIG. 1.

FIG. 5 is a first schematic flowchart of a manufacturing method of a mask according to an example of the disclosure.

FIG. 6A to FIG. 6C are schematic views showing a first operation of the manufacturing method of a mask according to an example of the disclosure.

FIG. 7 is a second schematic flowchart of a manufacturing method of a mask according to an example of the disclosure.

FIG. 8A to FIG. 8D are schematic views showing a second operation of the manufacturing method of a mask according to an example of the disclosure.

FIG. 9 is a third schematic flowchart of a manufacturing method of a mask according to an example of the disclosure.

FIG. 10 is a schematic view showing a third operation of the manufacturing method of a mask according to an example of the disclosure.

FIG. 11 is a schematic top view of a mask according to a second example of the disclosure.

FIG. 12 is a partial enlarged view of FIG. 11.

FIG. 13 is a schematic partial sectional view of FIG. 12 taken along line B-B′.

FIG. 14A and FIG. 14B are schematic views showing microscopic images of the example of FIG. 11.

FIG. 15A and FIG. 15B are schematic views showing photos of the example of FIG. 11.

### DETAILED DESCRIPTION OF PREFERRED EMBODIMENTS

The foregoing and other technical contents and other features and advantages of the present invention will be clearly presented from the following detailed description of a preferred embodiment in cooperation with the accompanying drawings. Directional terms mentioned in the following examples, for example, upper, lower, left, right, front, back, top or bottom, are only used to describe directions referring to the attached drawings. Therefore, the directional terms used are for illustration and not for limitation.

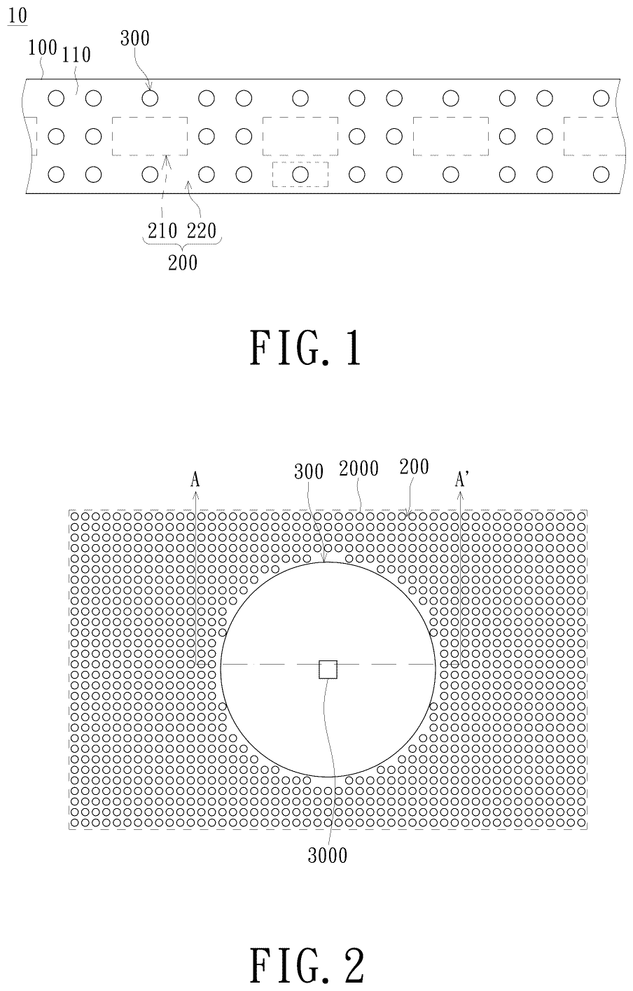

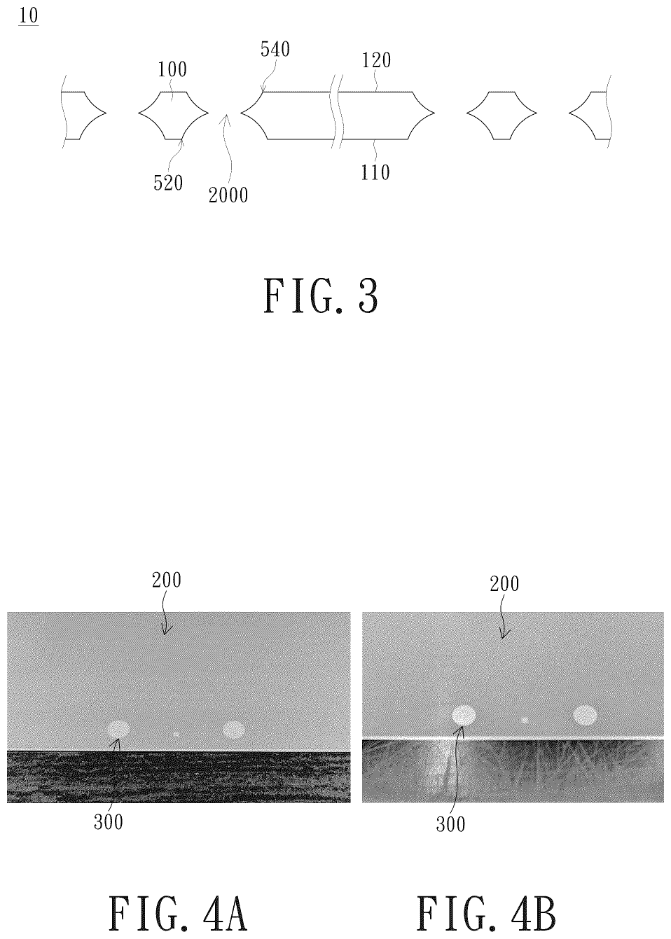

FIG. 1 is a schematic top view of a mask according to a first example of the disclosure. FIG. 2 is a partial enlarged view of the dashed box in FIG. 1. FIG. 3 is a schematic partial sectional view of FIG. 2 taken along line A-A′. A mask 10 according to an example of the disclosure can have a body in a form of a sheet or a plate. A material of the body is preferably metal. As shown in FIG. 1 and FIG. 3, in the example of the disclosure, the mask 10 can be substantially in a form of a rectangular sheet or a rectangular plate, and comprise a first surface 110 and a second surface 120 opposite to the first surface 110. In some examples, the mask 10 can have a length of, for example, 250 to 1800 mm, and a width of, for example, 50 to 400 mm. In addition, in some examples, the mask can have a thickness of, for example, 15 to 50 μm.

As shown in FIG. 1, FIG. 2 and FIG. 3, the mask 10 comprises a total etching area 200 and clearance areas 300. The mask 10 has a plurality of vias 2000 in the total etching area 200, and each via 2000 communicates the first surface 110 with the second surface 120. The via 2000 can have a first opening 520 on the first surface 110 and a second opening 540 on the second surface 120. The first opening 520 and the second opening 540 can have different sizes. In the example of the disclosure, for example, the first opening 520 is greater than the second opening 540. The plurality of clearance areas 300 are arranged in the total etching area 200. The clearance area 300 can have a through hole 3000 therein, and the clearance area 300 is surrounded by the vias 2000 of the total etching area 200. The through hole 3000 communicates the first surface 110 with the second surface 120. The through hole 3000 in the clearance area 300 can be used for, for example, alignment in the mask stretching operation of the mask 10, and for example, for monitoring the thickness of an evaporation material layer in the evaporation operation.

In a preferred example of the disclosure, as shown in FIG. 1, the total etching area 200 can further comprise a plurality of working areas 210 and a peripheral area 220. In some examples, the working area 210 and the plurality of vias 2000 therein have a pattern design, which can be used for, for example, implementing the pattern onto a substrate in the evaporation operation. The plurality of working areas 210 are spaced apart from each other, and the plurality of clearance areas 300 are arranged on a periphery of each working area 210. The peripheral area 220 preferably surrounds the plurality of working areas 210. For example, the peripheral area 220 includes a region between an edge of the mask 10 and the plurality of working areas 210. The plurality of clearance areas 300 can be further arranged between an edge of each working area 210 and the edge of the mask 10. The number and arrangement of the clearance areas 300 in FIG. 1 are only an example, and the number of the clearance areas 300 is not directly proportional to the size of the mask 10. The number and arrangement of the clearance areas 300 can be adjusted according to needs.

As shown in FIG. 1 to FIG. 3, the clearance area 300 is in a shape of a circle, which can also be a polygon. In addition, the plurality of clearance areas 300 can also be in different shapes. When the clearance area 300 is in the shape of a polygon, each interior angle of the polygon is greater than 90 degrees and preferably greater than or equal to 120 degrees, unless there are special cases (explained later). That is, in special cases, the interior angle of the polygon can be less than or equal to 90 degrees. In addition, the polygon can further be a convex polygon. The area of the clearance area 300 can be determined in a conventional manner according to the range occupied by the through hole 3000. For example, the area of the clearance area 300 can be approximately 1 mm² or less.

An actual appearance of the example of FIG. 1 can be as shown in FIG. 4A to FIG. 4B. FIG. 4A is an image taken from the second surface 120, and FIG. 4B is an image taken from the first surface 110. The clearance area 300 in this example of the disclosure has circular symmetry, and does not have a right-angled (90 degrees) structure, so it is less likely to form regional stress concentration, thus avoiding creasing. As shown in FIG. 4A to FIG. 4B, there is no crease at the junction between the clearance area 300 and the total etching area 200, exhibiting a flat appearance. Therefore, alignment errors can be avoided, for example, in the mask stretching operation, and moreover, inaccurate monitoring of the thickness can be avoided, for example, in the evaporation operation.

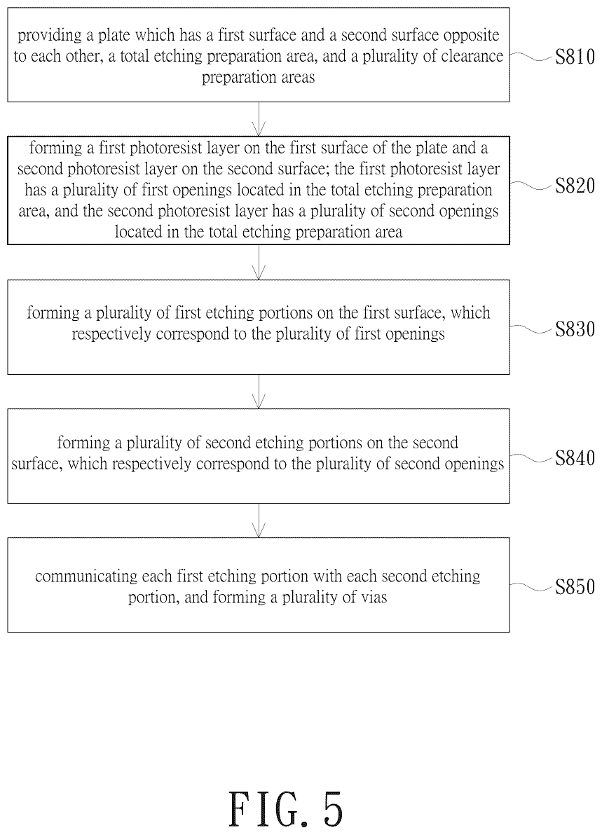

The disclosure further provides a manufacturing method of a mask, as shown in FIG. 5, comprising step S810 to step S850 as follows. Step S810: providing a plate which has a first surface and a second surface opposite to each other, a total etching preparation area, and a plurality of clearance preparation areas. Step S820: forming a first photoresist layer on the first surface of the plate and a second photoresist layer on the second surface; the first photoresist layer has a plurality of first openings located in the total etching preparation area, and the second photoresist layer has a plurality of second openings located in the total etching preparation area. Step S830: forming a plurality of first etching portions on the first surface, which respectively correspond to the plurality of first openings. Step S840: forming a plurality of second etching portions on the second surface, which respectively correspond to the plurality of second openings. Step S850: communicating each first etching portion with each second etching portion, and forming a plurality of vias.

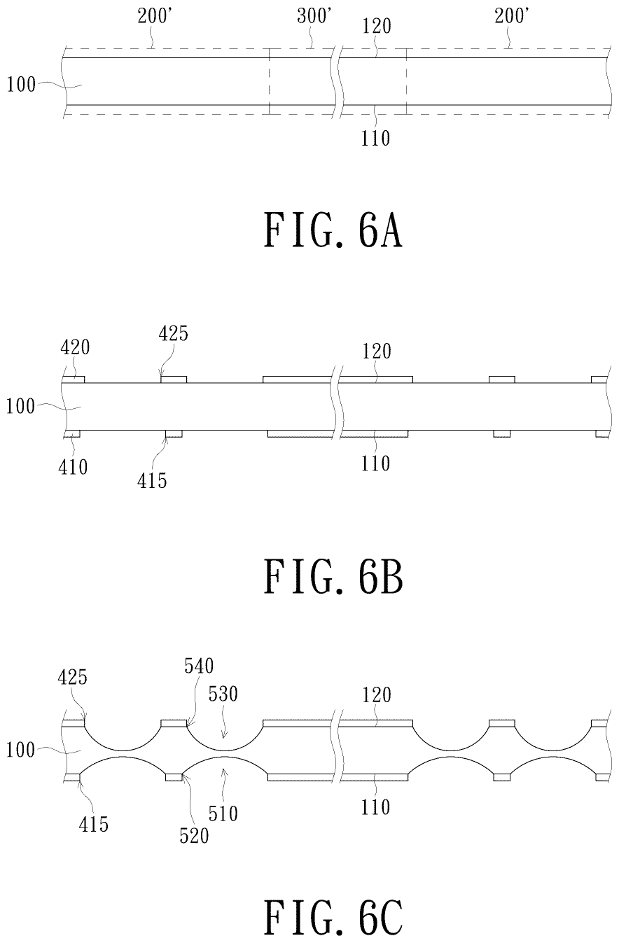

For the plate 100 provided in step S810, reference can be made to, for example, FIG. 6A. In addition, the plate 100 can be pretreated according to any conventional manner to adapt to step S820 to step S850. Step S820 can be carried out according to any conventional manner with reference to, for example, FIG. 6B, which can include, for example: coating a photoresist on the first surface 110, and carrying out exposure and development, so as to form a first photoresist layer 410 and a plurality of first openings 415 on the first surface 110; and coating a photoresist on the second surface 120, and carrying out exposure and development, so as to form a second photoresist layer 420 and a plurality of second openings 425 on the second surface 120. In a preferred example of the disclosure, the first opening 415 is greater than the second opening 425.

Step S830 to step S840 can be carried out according to any conventional manner with reference to, for example, FIG. 6C, which can include, for example: carrying out a first etching so that the plate 100 is etched by an etching solution from a part of the first surface 110 exposed by the first opening 415 and a part of the second surface 120 exposed by the second opening 425, thereby preliminarily forming a first etching portion 510 and a second etching portion 530. Step S850 can be carried out according to any conventional manner, which can include, for example: carrying out a second etching, so that the etching solution performs further etching at the first etching portion 510. Step S850 preferably further includes: forming a protective layer (not shown) on the second photoresist layer 420. The protective layer can fill the second etching portion 530, and the shape of the second etching portion 530 is maintained during the second etching. When the etching proceeds to the protective layer, the first etching portion 510 can be communicated with the second etching portion 530, and the via 2000 is formed. The first etching portion 510 has a first opening 520 on the first surface 110, and the second etching portion 530 has a second opening 540 on the second surface 120. In the example of the disclosure, the first opening 520 can be greater than the second opening 540. The example of the manufacturing method of a mask in the disclosure can further include removing the first photoresist layer 410, the second photoresist layer 420 and the protective layer. The removing can be carried out by any appropriate means, which will not be described in detail here.

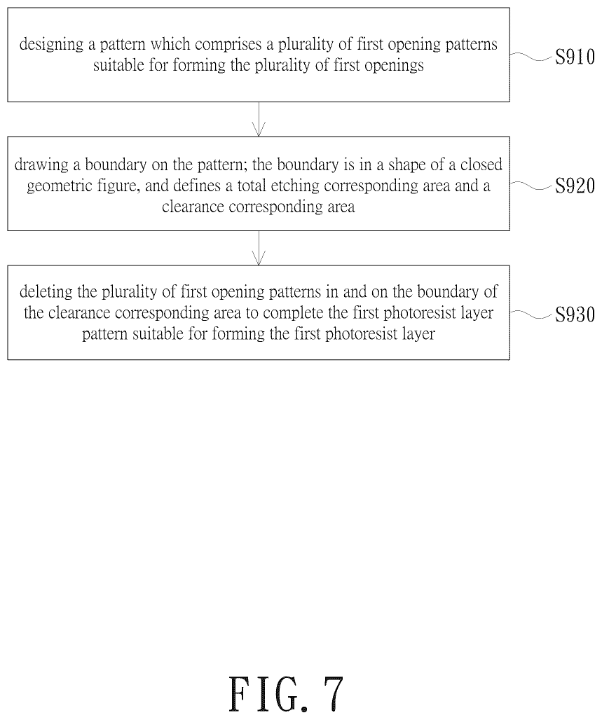

In the example of the disclosure, step S820 further comprises designing a first photoresist layer pattern, and designing a second photoresist pattern. In some examples, as shown in FIG. 7, the step of designing the first photoresist layer pattern can comprise step S910 to step S930 as follows. Step S910: designing a pattern which comprises a plurality of first opening patterns suitable for forming the plurality of first openings. Step S920: drawing a boundary on the pattern; the boundary is in a shape of a closed geometric figure, and defines a total etching corresponding area and a clearance corresponding area. Step S930: deleting the plurality of first opening patterns in and on the boundary of the clearance corresponding area to complete the first photoresist layer pattern suitable for forming the first photoresist layer. Step S910 can further include designing a range and a position of the through hole 3000.

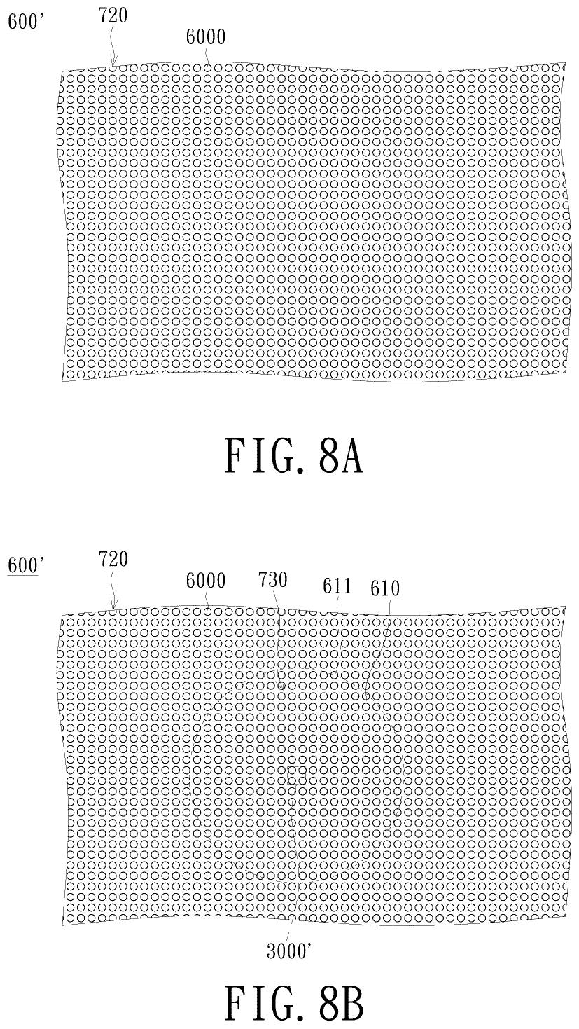

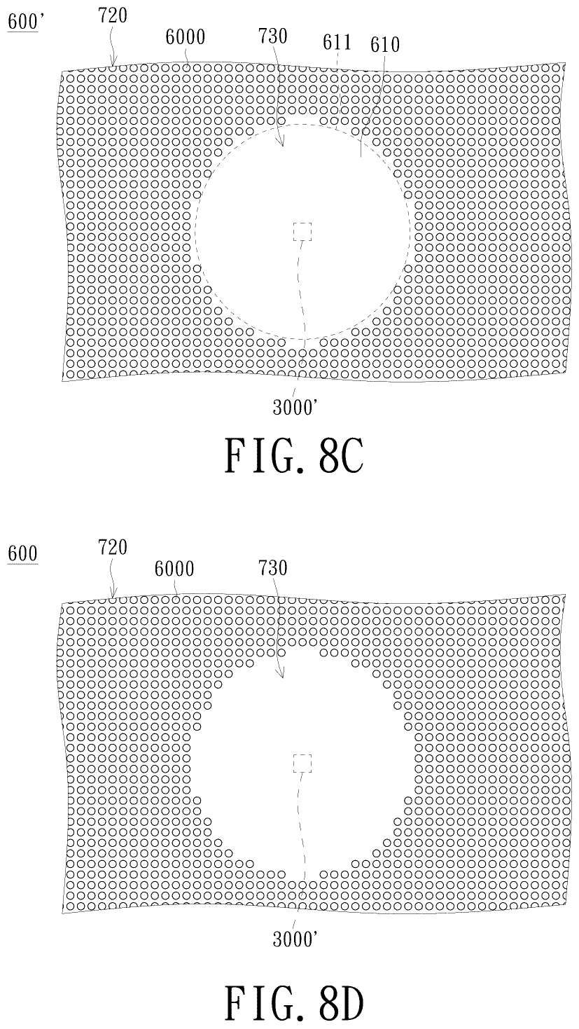

For the operations of step S910 to step S930, reference can be made to, for example, FIG. 8A to FIG. 8D. As shown in FIG. 8A, a pattern 600′ includes a plurality of first opening patterns 6000. The size or range of the pattern 600′ (FIG. 8A only shows a part of the pattern 600′) can preferably reflect, for example, the size or range of the subsequent first photoresist layer 410, and the first opening pattern 6000 can reflect the size, density and arrangement of the subsequent first openings 415, and further reflect the shape, density and arrangement of the first openings 520. As shown in FIG. 8B, the inside of the closed geometric FIG. 610 is preferably used as the clearance corresponding area 730, and the outside is used as the total etching corresponding area 720. The size of the clearance corresponding area 730 is preferably significantly different from a through hole range 3000′; for example, the clearance corresponding area 730 is sufficiently large relative to the through hole range 3000′ so as to be significantly different from the through hole range 3000′. For example, a diameter of the clearance corresponding area 730 is preferably greater than 100 μm. FIG. 8A to FIG. 8B only show a part of the pattern 600′ and one clearance corresponding area 730. However, a plurality of closed geometric figures 610 can be drawn in the whole pattern 600′ to define a plurality of clearance corresponding areas 730. The closed geometric FIG. 610 preferably reflects the shape of the clearance area 300, such as a circle and a polygon as described above, and each interior angle of the polygon is greater than 90 degrees and preferably greater than or equal to 120 degrees, unless there are special cases (explained later). The closed geometric FIG. 610 shown in FIG. 8B is in a shape of a circle.

As shown in FIG. 8C, in step S930, the first opening patterns 6000 in the closed geometric FIG. 610 are deleted. In the example of the disclosure, the first opening patterns 6000 through which the outline of the closed geometric FIG. 610 pass, i.e., the first opening patterns 6000 on the boundary 611 are also deleted, thereby completing the first photoresist layer pattern 600 shown in FIG. 8D. In short, since there is no first opening patterns 6000 in the clearance corresponding area 730 in the first photoresist layer pattern 600, in step S820, it is preferred to form the first openings 415 only in the total etching preparation area 200′, so that the first etching portions 510 and the vias 2000 are formed on the first surface 110 in the total etching preparation area 200′ in step S830 to step S850. In addition, step S830 to step S850 can further comprise carrying out etching to form the through hole 3000.

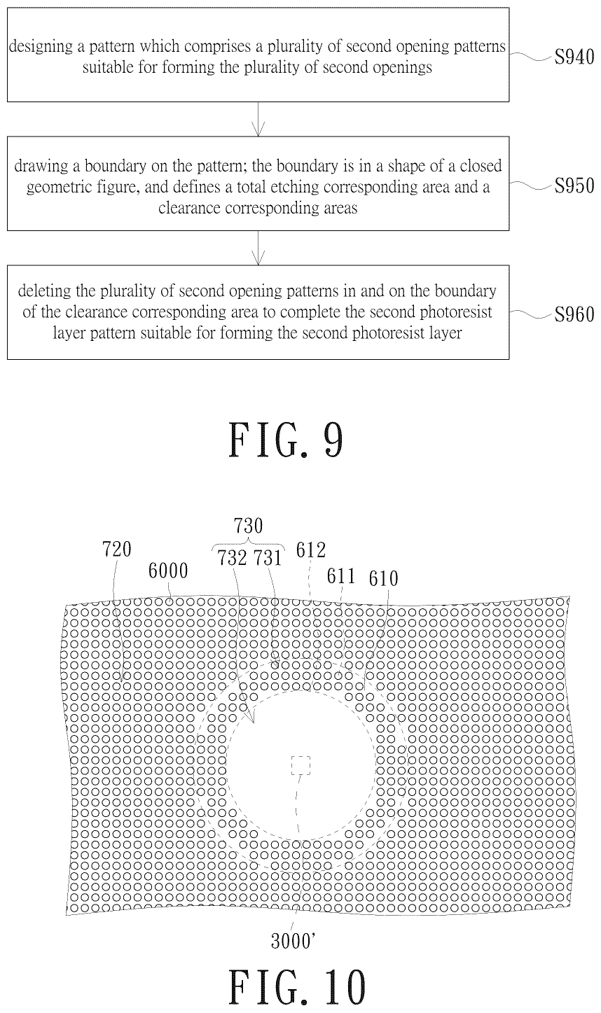

In some examples, as shown in FIG. 9, the step of designing the second photoresist layer pattern can comprise step S940 to step S960 as follows. Step S940: designing a pattern which comprises a plurality of second opening patterns suitable for forming the plurality of second openings. Step S950: drawing a boundary on the pattern; the boundary is in a shape of a closed geometric figure, and defines a total etching corresponding area and a clearance corresponding area. Step S960: deleting the plurality of second opening patterns in and on the boundary of the clearance corresponding area to complete the second photoresist layer pattern suitable for forming the second photoresist layer.

For the operations of step S940 to step S960, reference can be made to FIG. 8A to FIG. 8D. Preferably, the closed geometric figure in step S950 corresponds to the closed geometric figure in step S920 in position, and the shape, size and number of the closed geometric figures in step S950 are consistent with those of the closed geometric figures in step S920. In some examples of the disclosure, step S820 comprises step S910 to step S930 and step S940 to step S960, but is not limited thereto. For example, step S820 can also only comprise step S910 to step S930 or step S940 to step S960. When only step S910 to step S930 are performed, since the plurality of second openings 425 can be located in the clearance preparation area 300′ on the second surface 120, the second surface 120 can be etched in the clearance preparation area 300′, and the clearance area 300 can have etched grooves on the second surface 120 (explained later). When only step S940 to step S960 are performed, since the first surface 110 can be etched in the clearance preparation area 300′, the clearance area 300 can have etched grooves on the first surface 110.

In some examples, as shown in FIG. 10, step S920 or step S950 can further include drawing an inner boundary 612 in the closed geometric FIG. 610, which divides the clearance corresponding area 730 into a first region 731 and a second region 732. Preferably, the first region 731 surrounds the second region 732, and a percentage of an area of the first region 731 relative to an area of the second region 732 is preferably greater than 5%. Next, step S930 further includes deleting the plurality of first opening patterns 6000 located in the second region 732, and step S960 further includes deleting the plurality of second opening patterns located in the second region 732. Since the clearance corresponding area 730 in the first photoresist layer pattern 600 has the plurality of first opening patterns 6000 in the first region 731 and has no first opening patterns 6000 in the second region 732, in step S820, the plurality of first openings 415 can be formed in the total etching preparation area 200′ and a part of the clearance preparation area 300′, thereby, in step S830 to step S850, the part of the clearance preparation area 300′ on the first surface 110 is etched, so that the clearance area 300 can have the plurality of etched grooves on the first surface 110. Alternatively, in step S820, the plurality of second openings 425 can be formed in the total etching preparation area 200′ and a part of the clearance preparation area 300′, thereby, in step S830 to step S850, the part of the clearance preparation area 300′ on the second surface 120 can be etched, so that the clearance area 300 can have the plurality of etched grooves on the second surface 120.

In a preferred example of the disclosure, the etched grooves are formed in the clearance preparation area 300′ on one of the first surface 110 and the second surface 120. Further, the plate 100 can further comprise a first clearance region preparation area (not shown) and a second clearance region preparation area (not shown) in the clearance preparation area 300′ on the first surface 110, or further comprise a first clearance region preparation area (not shown) and a second clearance region preparation area (not shown) in the clearance preparation area 300′ on the second surface 120. The first clearance region preparation area surrounds the second clearance region preparation area. When the etched grooves are formed on the first surface 110, the first photoresist layer 410 in step S820 further has the plurality of first openings 415 in the first clearance region preparation area. When the etched grooves are formed on the second surface 120, the second photoresist layer 420 in step S820 further has the plurality of second openings 425 in the first clearance region preparation area. The mask 10 prepared according to the example of the manufacturing method in the disclosure has the clearance area 300 in the shape of a circle or a polygon and each interior angle of the polygon is preferably greater than or equal to 120 degrees, which thereby reduces or avoids creasing and helps in improving the manufacturing yield rate and the usability of the mask.

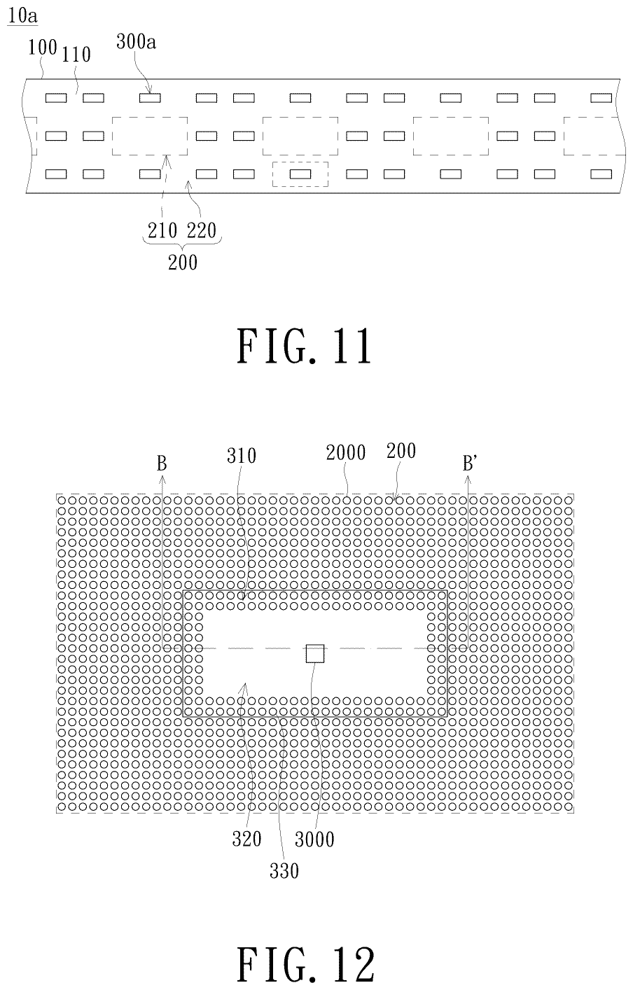

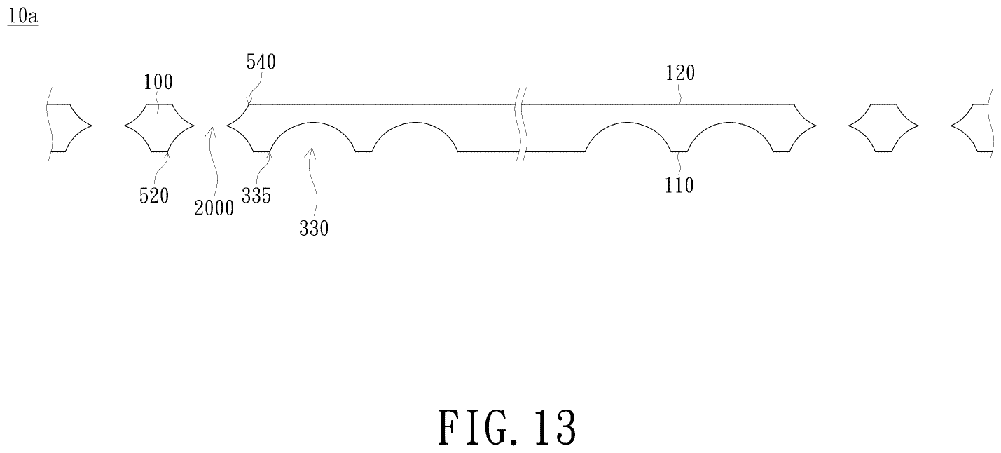

FIG. 11 is a schematic top view of a mask according to another example of the disclosure. FIG. 12 is a partial enlarged view of the dashed box in FIG. 11. FIG. 13 is a schematic partial sectional view of FIG. 12 taken along line B-B′. The example of FIG. 11 to FIG. 13 is different from the example of FIG. 1 to FIG. 3 mainly in that the clearance area 300a further comprises a first clearance region 310 and a second clearance region 320, and the first clearance region 310 surrounds the second clearance region 320; and the mask 10a has a plurality of etched grooves 330 in the first clearance region 310 and has the through hole 3000 in the clearance region 320. It has been tested that when a percentage of an area of the first clearance region 310 relative to an area of the clearance area 300a is greater than 5%, the creasing can be reduced or avoided. In a preferred example of the disclosure, a percentage of the area of the first clearance region 310 relative to the area of the clearance area 300a is preferably greater than or equal to 10%.

As shown in FIG. 13, the etched groove 330 is formed on the first surface 110, and an opening 335 of the etched groove is located on the first surface 110. However, the disclosure is not limited thereto. The etched groove 330 can also be formed on the second surface 120, and the opening 335 is located on the second surface 120. It should be noted that in the example of the disclosure, the etched groove 330 refers to a groove formed by etching the plate 100 partially from the first surface 110 or the second surface 120 without etching through the plate 100. The example of the disclosure does not limit the depth of the etched groove 330. For example, the depth of the etched groove 330 can approximate a depth of the first etching portion 510, but is not limited thereto.

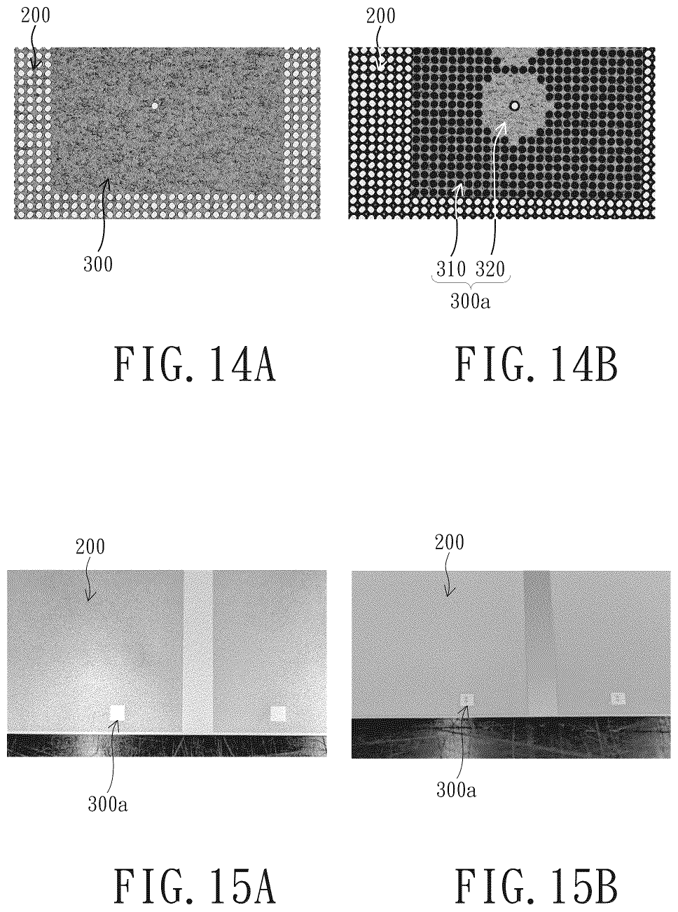

FIG. 14A and FIG. 14B are schematic views showing microscopic images of the mask 10a. FIG. 14A is an image taken from the second surface 120, which shows that there is no opening 335 of the etched groove 330 in the clearance area 300a. FIG. 14B is an image taken from the first surface 110, which shows that the etched grooves 330 of the clearance area 300a in the first clearance region 310 surround the second clearance region 320. For the forming method of the etched grooves 330, reference can be made to the description above. The forming method includes, as in step S920 to step S930 or step S950 to S960, drawing the inner boundary 612 in the closed geometric FIG. 610 to divide the clearance corresponding area 730 into the first region 731 and the second region 732, and deleting the plurality of first opening patterns 6000 or the plurality of second opening patterns in the second region 732.

As shown in FIG. 11 to FIG. 13, the clearance area 300a is in a shape of a rectangle. However, the clearance area 300a can also be in a shape of a circle or a polygon, such as a pentagon or a hexagon. In the example of the disclosure, generally, in a case where an interior angle of the polygon is less than or equal to 90 degrees, for example, when the polygon is a rectangle, the clearance area 300a is provided with the first clearance region 310 having the plurality of etched grooves 330. In a preferred example of the disclosure, in a case where an interior angle of the polygon is less than 120 degrees, the clearance area 300a is provided with the first clearance region 310 having the plurality of etched grooves 330. Since the plurality of etched grooves 330 surround the second clearance region 320 and the total etching area 200 is adjacent to the first clearance region 310 having the plurality of etched grooves 330, in the example, the structural difference between the clearance area 300 and the total etching area 200 is reduced, so that the stress gradient can be reduced, thereby avoiding creasing.

An actual appearance of the example of FIG. 11 can be as shown in FIG. 15A to FIG. 15B. FIG. 15A is an image taken from the second surface 120, and FIG. 15B is an image taken from the first surface 110. As shown in FIG. 15A to FIG. 15B, there is no visible crease at the junction between the clearance area 300a and the total etching area 200, exhibiting a flat appearance. Therefore, alignment errors can be avoided, for example, in the mask stretching operation, and moreover, inaccurate monitoring of the thickness can be avoided, for example, in the evaporation operation.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A mask, comprising a first surface and a second surface opposite to the first surface, and having:
a total etching area; the mask having a plurality of vias in the total etching area, and each of the vias communicating the first surface with the second surface; and
a plurality of clearance areas; the plurality of clearance areas being arranged in the total etching area, and the plurality of vias of the total etching area surrounding each of the clearance areas;
wherein each clearance area further has a through hole therein, and the through hole communicates the first surface with the second surface; each of the clearance areas is in a shape of a circle or a polygon; wherein when each interior angle of the polygon is less than 120 degrees, the clearance area further comprises a first clearance region and a second clearance region; the first clearance region surrounds the second clearance region, and the mask has a plurality of etched grooves in the first clearance region.

2. The mask according to claim 1, wherein a percentage of an area of the first clearance region relative to an area of the clearance area is greater than 5%, and the plurality of etched grooves are opened on the first surface or the second surface.

3. The mask according to claim 1, wherein a percentage of an area of the first clearance region relative to an area of the clearance area is further greater than or equal to 10%.

4. The mask according to claim 1, wherein the clearance area is in a shape of a rectangle, and the clearance area comprises the first clearance region and the second clearance region.

5. The mask according to claim 1, wherein the total etching area further comprises a plurality of working areas, and the plurality of working areas are spaced apart from each other; wherein the plurality of clearance areas are arranged on a periphery of each working area.

6. The mask according to claim 5, wherein the total etching area further comprises a peripheral area surrounding the plurality of working areas; and the plurality of clearance areas are further arranged between an edge of each working area and an edge of the mask.

7. A mask, comprising a first surface and a second surface opposite to the first surface, and having:
a total etching area; the mask having a plurality of vias in the total etching area, and each of the vias communicating the first surface with the second surface; and
a plurality of clearance areas, arranged in the total etching area, at least one of the clearance areas comprising a first clearance region and a second clearance region, the first clearance region surrounding the second clearance region, and a percentage of an area of the first clearance region relative to an area of the at least one clearance area being greater than 5%;
wherein the mask has a plurality of etched grooves in the first clearance region, and the second clearance region has a through hole; the plurality of etched grooves are opened on the first surface or the second surface, and the through hole communicates the first surface with the second surface.

8. A manufacturing method of a mask, comprising:
providing a plate, the plate having a first surface and a second surface opposite to each other, a total etching preparation area, and a plurality of clearance preparation areas;
forming a first photoresist layer on the first surface of the plate, and forming a second photoresist layer on the second surface; wherein the first photoresist layer has a plurality of first openings located in the total etching preparation area, and the second photoresist layer has a plurality of second openings located in the total etching preparation area;
forming a plurality of first etching portions on the first surface, the plurality of first etching portions being respectively corresponding to the plurality of first openings;
forming a plurality of second etching portions on the second surface, the plurality of second etching portions being respectively corresponding to the plurality of second openings; and
communicating each first etching portion with each second etching portion, and forming a plurality of vias.

9. The manufacturing method of a mask according to claim 8, wherein the clearance preparation area of the first surface further comprises a first clearance region preparation area and a second clearance region preparation area, the first clearance region preparation area surrounding the second clearance region preparation area, and the first photoresist layer further has a plurality of first openings located in the first clearance region preparation area; and the step of forming the plurality of first etching portions further comprises forming a plurality of etched grooves in the first clearance region preparation area.

10. The manufacturing method of a mask according to claim 8, wherein the clearance preparation area of the second surface further comprises a first clearance region preparation area and a second clearance region preparation area, the first clearance region preparation area surrounding the second clearance region preparation area, and the second photoresist layer further has a plurality of second openings located in the second clearance region preparation area; and the step of forming the plurality of second etching portions further comprises forming a plurality of etched grooves in the second clearance region preparation area.

11. The manufacturing method of a mask according to claim 8, wherein each first etching portion further has a first opening, and each second etching portion further has a second opening, the first opening being greater than the second opening.

12. The manufacturing method of a mask according to claim 8, wherein the step of forming the first photoresist layer further comprises designing a first photoresist layer pattern, comprising:
designing a pattern; the pattern comprising a plurality of first opening patterns suitable for forming the plurality of first openings;
drawing a boundary on the pattern; the boundary being in a shape of a closed geometric figure, and the boundary defining a total etching corresponding area and a clearance corresponding area; and
deleting the plurality of first opening patterns in and on the boundary of the clearance corresponding area to complete the first photoresist layer pattern suitable for forming the first photoresist layer.

13. The manufacturing method of a mask according to claim 12, further comprising forming a total etching area in the total etching preparation area according to the total etching corresponding area, and forming a plurality of clearance areas in the plurality of clearance corresponding areas according to the plurality of clearance preparation areas.

14. The manufacturing method of a mask according to claim 8, wherein the step of forming the second photoresist layer further comprises designing a second photoresist layer pattern, comprising:
designing a pattern; the pattern comprising a plurality of second opening patterns suitable for forming the plurality of second openings;
drawing a boundary on the pattern; the boundary being in a shape of a closed geometric figure, and the boundary defining a total etching corresponding area and a clearance corresponding area; and
deleting the plurality of second opening patterns in and on the boundary of the clearance corresponding area to complete the second photoresist layer pattern suitable for forming the second photoresist layer.

15. The manufacturing method of a mask according to claim 14, further comprising forming a total etching area in the total etching preparation area according to the total etching corresponding area, and forming a plurality of clearance areas in the plurality of clearance corresponding areas according to the plurality of clearance preparation areas.
